(19) United States
(12) Patent Application Publication
(10) Pub. No.: US 2008/0176404 A1
(43) Pub. Date: Jul. 24, 2008

(54) Method for fabricating semiconductor device

(75) Inventors: Kunihiko Nagase, Kawasaki (JP); Akihiro Hasegawa, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki-shi (JP)

(21) Appl. No.: 11/907,737

(22) Filed: Oct. 17, 2007

Related U.S. Application Data
(62) Division of application No. 10/816,959, filed on Apr. 5, 2004, now abandoned.

(30) Foreign Application Priority Data
Dec. 25, 2003 (JP) 2003-430387

(51) Int. Cl. H01L 21/768

(52) U.S. Cl. 438/700; 257/E21.577

(57) ABSTRACT

The method for fabricating the semiconductor device comprises the step of forming an insulating film 14 having an opening 18; the step of forming an organic resist film 20a; the step of forming over the organic resist film 20a a mask film 20b having etching characteristics different from those of the organic resist film 20a; the step of forming an opening in the mask film 20b; and the step of etching the organic resist film 20a with the mask film 20b as the mask. In the step of etching the organic resist film, the organic resist film 20a is etched with a mixed gas of nitrogen gas and oxygen gas.

### CROSS-REFERENCE TO RELATED APPLICATIONS

This application is a division of U.S. application Ser. No. 10/816,959, filed on Apr. 5, 2004 which is based upon and claims the benefit of priority from the prior Japanese Patent Application No. 2003-430387, filed on Dec. 25, 2003, the entire contents of which are incorporated herein by reference.

### BACKGROUND OF THE INVENTION

The present invention relates to a method for fabricating a semiconductor device, more specifically a method for fabricating a semiconductor device including the step of processing a lower layer by a multilayer resist process.

As semiconductor devices are larger-scaled and more integrated, patterns are increasingly downsized. The downsizing of semiconductor devices is realized by shortening the light source wavelength of exposure systems used in the photolithography. Presently, as the light source, argon fluoride (ArF) excimer lasers of a 0.193 μm-wavelength are widely used.

The photoresist film used in the photolithography using ArF excimer laser (ArF resist film) does not have sufficient etching selectivity with respect to the constituent materials of the semiconductor devices, so that it is difficult to accurately process lower layers with a single layer of the ArF resist film as the mask.

As a process which solves this difficulty, a multilayer resist process is developed. In the multilayer resist process, the resist film is formed of a multilayer so as to enhance the function as a mask material for the lower film processing to thereby precisely process target layers.

The multilayer resist process is described in, e.g., Reference 1 (Japanese published unexamined patent application No. 2002-093778). The multilayer resist process described in Reference 1 will be summarized.

First, on a lower layer (silicon oxide-based insulating film) to be processed, a lower resist film (spin-on type carbon film) having etching selectivity with respect to the lower material, an oxide film (SOG film) having etching selectivity with respect to the upper resist film, and a photoresist film are sequentially formed.

Then, the photoresist film is patterned by photolithography, and with the photoresist film as the mask, the oxide film is etched to transfer a pattern of the photoresist film onto the oxide film.

Next, with the patterned oxide film as the mask, the lower resist film is etched to transfer the pattern of the oxide film onto the lower resist film.

Next, with the lower resist film as the mask, the lower layer is processed.

Reference 2 (Pamphlet of International Patent Application Unexamined Publication No. 00/079586), Reference 3 (Japanese published unexamined patent application No. 2001-110784), Reference 4 (Japanese published unexamined patent application No. 2002-110647), Reference 5 (Japanese published unexamined patent application No. 2002-373937) and Reference 6 (Japanese published unexamined patent application No. 2003-045964) also disclose related arts.

### SUMMARY OF THE INVENTION

The inventors of the present application have made earnest studies of the application of above-described multilayer resist process to the dual damascene process. However, it has been found that in the process of the preceding via mode in which via-holes are formed before interconnection trenches are formed, damages are introduced into the lower structures in the process of forming the interconnection trenches.

An object of the present invention is to provide a method for fabricating a semiconductor device using the multilayer resist process, more specifically a method for fabricating a semiconductor device which can pattern the lower resist film without damaging the lower structure and, by using the lower resist film, can process a downsized pattern with high controllability.

According to one aspect of the present invention, there is provided a method for fabricating a semiconductor device comprising the steps of: forming over an organic resist film a mask film having etching characteristics different from those of the organic resist film and having an opening formed in a prescribed region; and etching the organic resist film with the mask film as a mask, in the step of etching the organic resist film, the organic resist film being etched with a mixed gas of nitrogen gas and oxygen gas.

According to another aspect of the present invention, there is provided a method for fabricating a semiconductor device comprising the steps of: forming an insulating film having a first opening in a first region; forming an organic resist film over the insulating film and in the first opening; forming a mask film having etching characteristics different from those of the organic resist film over the organic resist film; forming a second opening in the mask film in a second region including at least a part of the first region; and etching the organic resist film with the mask film as a mask, in the step of etching the organic resist film, the organic resist film being etched with a mixed gas of nitrogen gas and oxygen gas.

According to the present invention, in the dual damascene process using the preceding via mode using a multilayer resist, N₂/O₂ or N₂/O₂/CF gas is used in etching a lower resist film in forming an interconnection trench, whereby the lower resist film is patterned without damaging the lower structure, and the lower resist film is vertically processed. Accordingly, with the thus formed lower resist film as a mask, the lower structure is etched to thereby process a downsized pattern with good controllability.

### BRIEF DESCRIPTION OF THE DRAWINGS

FIGS. 1A-1C, 2A-2C, 3A-3B, 4A-4B and 5A-5C are sectional views of the semiconductor device in the steps of the method for fabricating the same according to one embodiment of the present invention, which show the method.

FIGS. 6A and 6B are pictures of sectional configurations formed by etching the resist film with NH₃ gas.

FIG. 7 is a graph of the oxygen flow rate ratio dependency of the bowing amount in the etching with N₂/O₂ gas.

FIGS. 8A and 8B are pictures of sectional configurations formed by etching the resist film with an oxygen gas or a mixed gas of oxygen and nitrogen.

FIGS. 9A and 9B are sectional configurations of the resist film etched under low chamber internal pressure and under high chamber internal pressure.

FIGS. 10A-10C are sectional configurations formed by etching the resist film with N₂/O₂ gas.

FIG. 11 is a graph of the oxygen flow rate ratio dependency of the bowing amount in the etching with N₂/O₂/C₄F₆ gas.

FIG. 12 is a sectional configuration formed by etching the resist film with N₂/O₂/C₄F₆ gas.

### DETAILED DESCRIPTION OF THE INVENTION

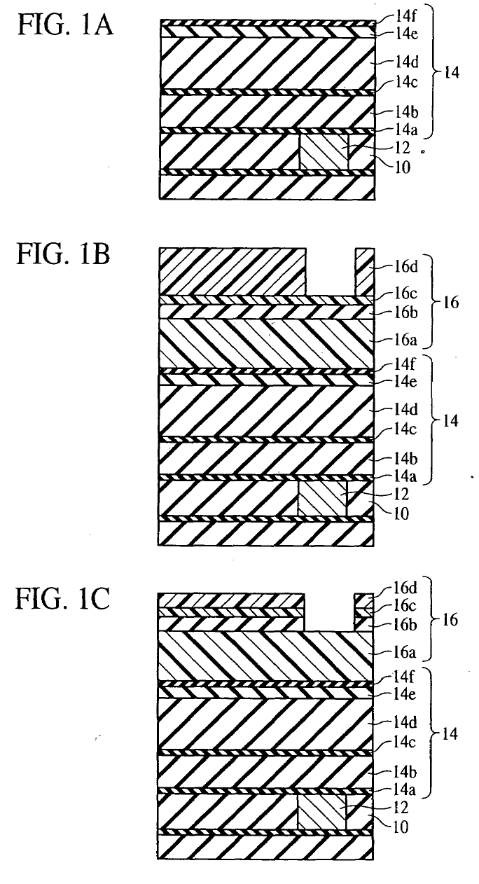

The method for fabricating the semiconductor device according to one embodiment of the present invention will be explained with reference to FIGS. 1A to 12.

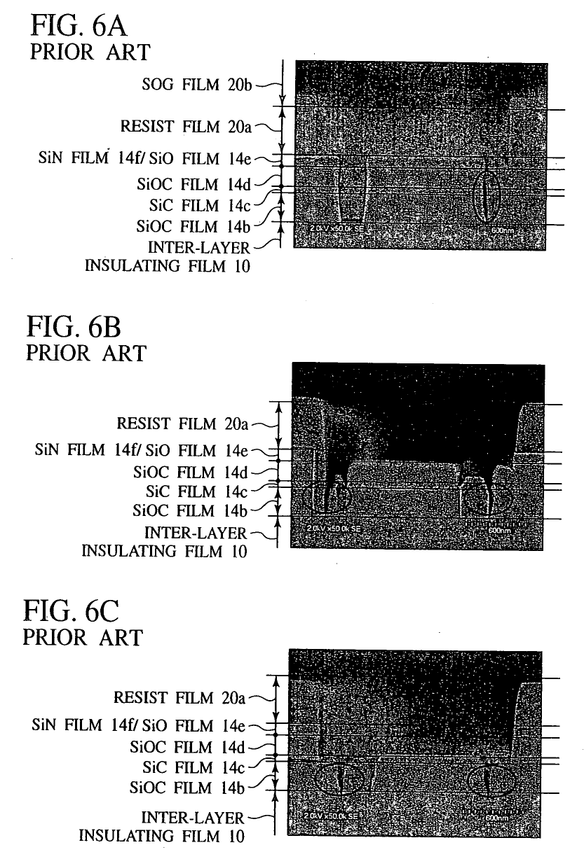

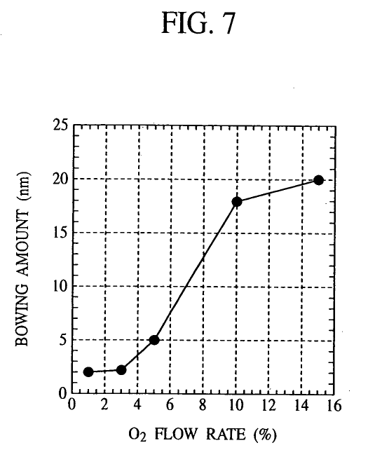

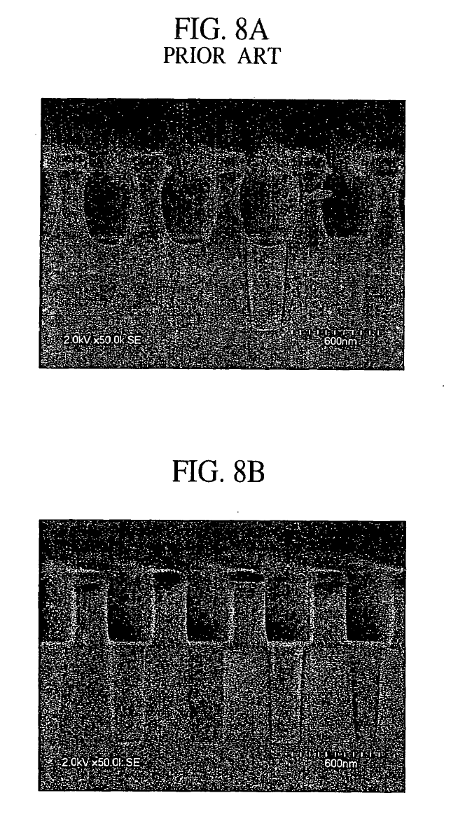

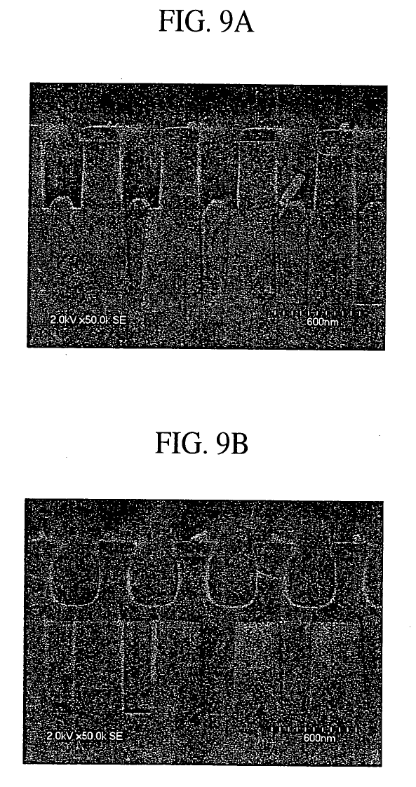

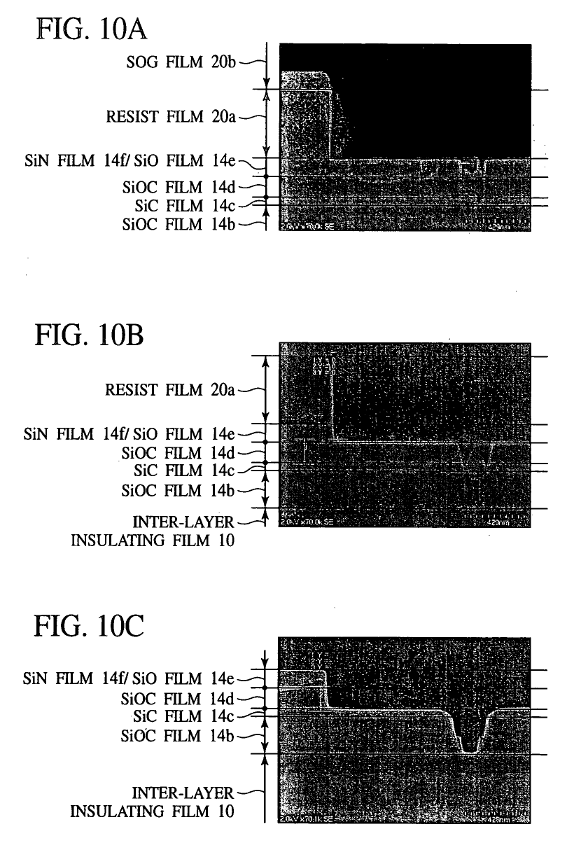

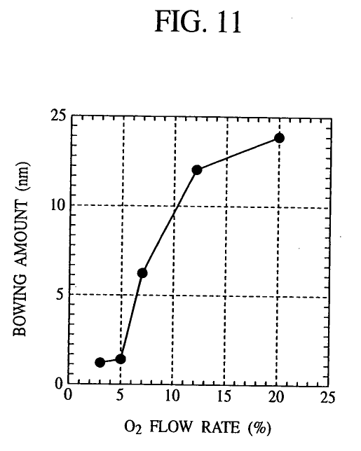

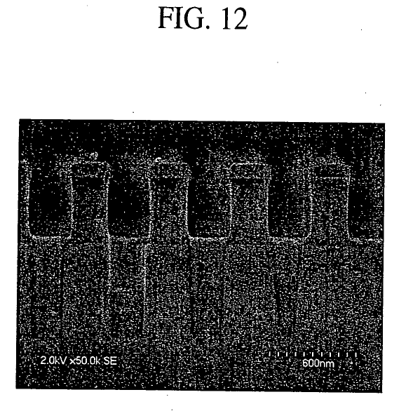

FIGS. 1A to 5C are sectional views of a semiconductor device in the steps of the method for fabricating the same according to the present embodiment, which show the method. FIGS. 6A and 6B are pictures of sectional configurations formed by etching the resist film with NH₃ gas. FIG. 7 is a graph of the oxygen flow rate ratio dependency of the bowing amount in the etching with N₂/O₂ gas. FIGS. 8A and 8B are pictures of sectional configurations formed by etching the resist film with an oxygen gas or a mixed gas of oxygen and nitrogen. FIGS. 9A and 9B are sectional configurations of the resist film etched under low chamber internal pressure and under high chamber internal pressure. FIGS. 10A-10C are sectional configurations formed by etching the resist film with N₂/O₂ gas. FIG. 11 is a graph of the oxygen flow rate ratio dependency of the bowing amount in the etching with N₂/O₂/C₄F₆ gas. FIG. 12 is a sectional configuration formed by etching the resist film with N₂/O₂/C₄F₆ gas.

Before the present invention is specifically described, the method for fabricating the semiconductor device the present invention is applied to will be explained with reference to FIGS. 1A to 5C.

First, an SiC film 14a of, e.g., a 50 nm-thick, an SiOC film 14b of, e.g., a 250 nm-thick, an SiC film 14c of, e.g., a 30 nm-thick, an SiOC film 14d of, e.g., a 200 nm-thick, an SiO film 14e of, e.g., a 100 nm-thick and an SiN film 14f of, e.g., a 50 nm-thick are sequentially deposited by, e.g., CVD method on an inter-layer insulating film 10 with an interconnection 12 of mainly copper buried in (FIG. 1A). An inter-layer insulating film 14 of these films is thus formed. The SiC film 14a, the SiC film 14c and the SiN film 14f are used respectively as a barrier layer, an intermediate stopper layer and a hard mask. The inter-layer insulating film 10 is formed on a semiconductor substrate with devices, such as transistors, etc., formed on.

Next, on the inter-layer insulating film 14, a resist film 16a of an organic resist material of, e.g., a 500 nm-thick, an SOG film 16b of, e.g., a 100 nm-thick, a BARC film 16 of, e.g., a 82 nm-thick and a resist film 16d of, e.g., a 300 nm-thick are formed by, e.g., spin coating method. A multilayer resist film 16 of these films is thus formed on the inter-layer insulating film 14. The resist film 16a is the resist film for etching the inter-layer insulating film 14, the SOG film 16b is the hard mask for patterning the resist film 16a, and the BARC film 16cis an organic anti-reflection film, and the resist film 16d is, e.g., a photosensitive ArF photoresist.

Then, the resist film 16d is patterned by photolithography to remove the resist film 16d in the region for a via-hole to be formed in (FIG. 1B).

Then, with the resist film 16d as the mask, the BARC film 16cand the SOG film 16b are anisotropically etched to transfer the pattern of the resist film 16d onto the SOG film 16b (FIG. 1C). The BARC film 16c and the resist film 16b are anisotropically etched, e.g., by a reactive plasma etching system under a 50 mTorr chamber internal pressure, at a 300 W power, with CF₄ as the etching gas, at a 100 sccm CF₄ flow rate, and for a 60 second etching period of time.

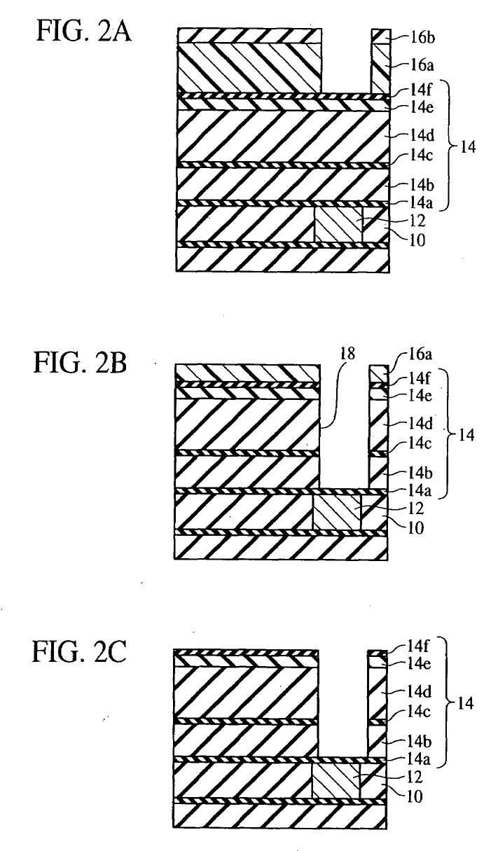

Then, with the SOG film 16b as the mask, the resist film 16a is dry etched to remove the resist film 16a in the region for a via-hole to be formed in (FIG. 2A). The BARC film 16c and the resist film 16d on the SOG film 16b are removed in this etching. The resist film 16a is anisotropically etched, e.g., by, a reactive plasma etching system under a 20 mTorr chamber internal pressure, at a 200 W power, with N₂/H₂ as the etching gas, at a 200/200 sccm N₂/H₂ flow rate, and for a 200 second etching period of time.

Then, with the resist film 16a as the mask, the SiN film 14f, the SiO film 14e, the SIOC film 14d, the SiC film 14c and the SiOC film 14b are anisotropically etched to open the via-hole 18 down to the SiC film 14a (FIG. 2B). The SOG film 16b on the resist film 16a is removed in this etching. The SiN film 14f, the SiO film 14e, the SIOC film 14d, the SiC film 14c and the SIOC film 14b are anisotropically etched, e.g., by reactive plasma etching system, under a 35 mTorr chamber internal pressure, at a 1000 W power, with C₅F₈/Ar/O₂ as the etching gas, a 10/500/12 sccm C₅F₈/Ar/O₂ flow rate, and a 40 second etching period of time.

Then, the resist film 16a is removed by ashing (FIG. 2C). The resist film 16a is ashed by a plasma ashing system, e.g., under a 10 mTorr chamber internal pressure, at a 300 W power, with O₂ as the ashing gas, at a 300 sccm O₂ flow rate, and a 48 second ashing period of time.

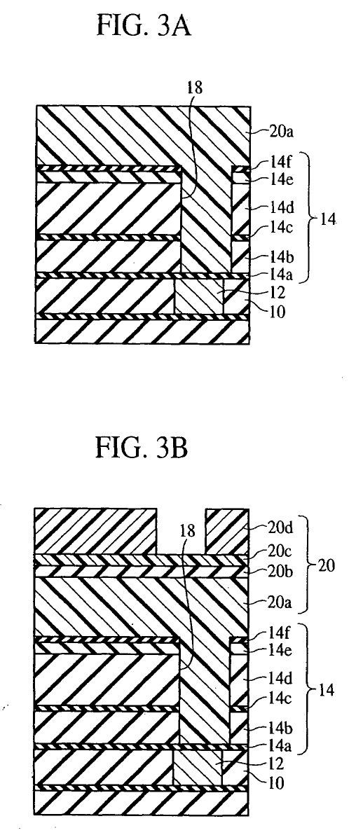

Next, a resist film 20a of an organic resist material of, e.g., a 500 nm-thick is formed by, e.g., spin coating method. The resist film 20a is formed, filling the via-hole 18 (FIG. 3A). Preferably, the surface of the resist film 20a is flat, because films to be formed on the resist film 20a can be flat, which permits photolithography to be performed without considering the problem of the depth of focus.

Then, an SOG film 20b of, e.g., a 100 nm-thick, a BARC film 20c of, e.g., a 82 nm-thick and a resist film 20d of, e.g., a 300 nm-thick are formed on the resist film 20a by, e.g., spin coating method. On the SiN film 14f, a multilayer resist film 20 of thus formed the resist film 20a, the SOG film 20b, the BARC film 20c and the resist film 20d is formed. The resist film 20a is the resist film to be used in etching the inter-layer insulating film 14, the SOC film 20b is to be used as the hard mask for patterning the resist film 20a, the BARC film 20 is an anti-reflection film, and the resist film 20d is, e.g., a photosensitive ArF photoresist.

Then, the resist film 20d is patterned by photolithography to move the resist film 20d in the region for an interconnection trench to be formed in (FIG. 3B).

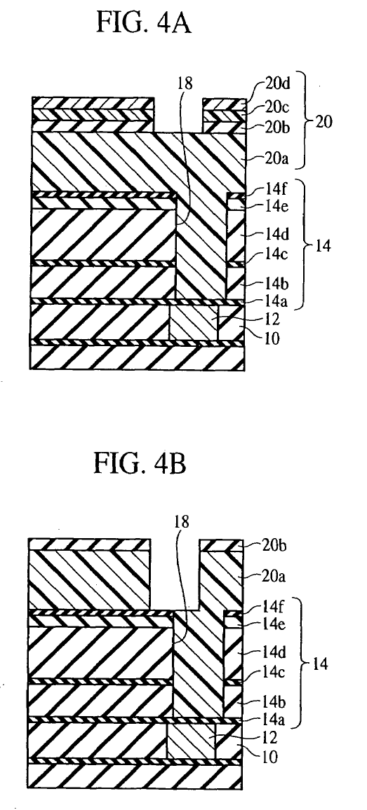

Next, with the resist film 20d as the mask, the BARC film 20 and the SOG film 20b are anisotropically etched to transfer the pattern of the resist film 20d onto the SOG film 20b (FIG. 4A). The BARC film 20c and the SOG film 20b are anisotropically etched, e.g., by a reactive plasma etching system, under a 50 mTorr chamber internal pressure, at a 300 W power, with CF₄ as the etching gas, at a 100 sccm CF₄ flow rate, and a 60 second etching period of time.

Then, with the SOG film 20b as the mask, the resist film 20a is dry etched to remove the resist film 20a in the region for the interconnection trench to be formed in. At this time, the resist film 20a is left in the via-hole 18 (FIG. 4B). The BARC film 20c and the resist film 20d on the SOG film 20b are removed in this etching.

The resist film 20a is anisotropically etched by, e.g., a reactive plasma etching system, e.g., under a 35 mTorr chamber internal pressure, at a 100 W power, with N₂/O₂ as the etching gas and at a 290/10 sccm N₂/O₂ flow rate, or, e.g., under a 40 mTorr chamber internal pressure, at a 150 W power, with N₂/O₂/C₄F₆ as the etching gas and a 250/50/5 sccm N₂/O₂/C₄F₆ flow rate. As will be described later, this etching step mainly characterizes the present invention.

Then, with the resist film 20a as the mask, the SiN film 14f and the SiO film 14e are anisotropically etched to remove the SiN film 14 and the SiO film 14e in the region for an interconnection trench to be formed in. The SiN film 14f is anisotropically etched, e.g., by a reactive plasma etching system, under a 40 mTorr chamber internal pressure, at a 200 W power, with CHF₃/Ar/O₂ as the etching gas, at a 20/200/10 sccm CHF₃/Ar/O₂ flow rate. The SiO film 14e is anisotropically etched, e.g., by a reactive plasma etching system under a 60 mTorr chamber internal pressure, at a 200 W power, with C₄F₆/Ar/O₂ as the etching gas and at a 30/400/20 sccm C₄F₆/Ar/O₂ flow rate.

Next, with the resist film 20a as the mask and the SiC film 14c as the stopper, the SIOC film 14d is anisotropically etched to form the interconnection trench 22 in the SIOC film 14c. The SOG film 20b on the resist film 20a is removed by this etching. The SIOC film 14d is anisotropically etched, e.g., by a reactive plasma etching system under a 35 mTorr chamber internal pressure, at a 100 W power, with N₂/O₂ as the etching gas, at a 290/10 sccm N₂/O₂ flow rate and a 200 second etching period of time.

Then, the resist film 20a is removed by ashing. The resist film 20a is ashed by a plasma ashing system, e.g., under a 10 mTorr chamber internal pressure, at a 300 W power, with O₂ as the ashing gas, at a 300 sccm O₂ flow rate and a 48 second ashing period of time.

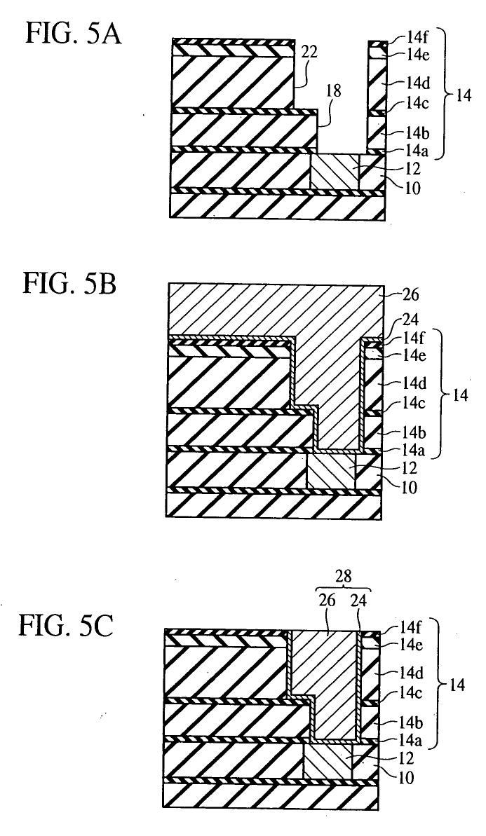

Next, the SiC film 14a on the bottom of the via-hole 18 is anisotropically etched to open the via-hole 18 down to the interconnection 12 (FIG. 5A). The SiC film 14a is anisotropically etched, e.g., by a reactive plasma etching system, under a 50 mTorr chamber internal pressure, at a 400 W power, with CH₂F₂/Ar/O₂ as the etching gas and at a 20/200/25 sccm CH₂F₂/Ar/O₂ flow rate.

Then, a barrier metal and a Cu seed are deposited by sputtering, and then Cu plating is performed. Thus, the via-hole 18 and the interconnection trench 22 are filled with a barrier metal 24 and a Cu film 26 (FIG. 5B).

Next, the Cu film 26 and the barrier metal 24 are polished by CMP method to leave the Cu film 26 and the barrier metal 24 selectively in the via-hole 18 and the interconnection trench 22. Thus, an interconnection 28 formed of the barrier metal 24 and the Cu film 26 and connected to the interconnection 12 is formed in the via-hole 18 and the interconnection trench 22 (FIG. 5C).

Hereafter, as required, interconnection layers are repeatedly formed on the interconnection 28 to fabricate a semiconductor device having the multi-level interconnections.

The present invention is characterized mainly in that in the above-described method for fabricating the semiconductor device, N₂/O₂ gas or N₂/O₂/CF gas is used as the etching gas for etching the resist film 20a in the step illustrated in FIG. 4B.

Conventionally, NH₃ and N₂/H₂ have been predominantly used in etching organic resist films used as the mask for etching inter-layer insulating films. However, the earnest studies of the inventors of the present application have found that in the above-described method for fabricating the semiconductor device, etching the resist film 20a with NH₃ or N₂/H₂ in the step of FIG. 4B generates cracks down to the inter-layer insulating film 10.

FIGS. 6A-6C are pictures of sectional configurations formed by etching the resist film 20a with NH₃ as the etching gas, which were taken by a scanning electron microscope. FIG. 6A is the sectional configuration immediately after the resist film 20a has been etched. FIG. 6B is the sectional configuration immediately after the SiN film 14f and the SiO film 14e have been etched. FIG. 6C is the sectional configuration immediately after the interconnection trench 22 has been formed and before the ashing.

As seen in FIG. 6A, immediately after the resist film 20a has been etched, a crack (circled in the drawing) is observed between the resist film 20a and the side wall of the via-hole 18. The crack is increased after the SiN film 14f and the SiO film 14e have been etched (see FIG. 6B). Then, after the interconnection trench 22 has been formed, the crack is further increased down to even the inter-layer insulating film 10 with the interconnection layer 12 buried in (FIG. 6C). There is the risk that such crack will much affect the reliability of the semiconductor device, and the generation of the crack must be prevented.

The mechanism that the crack is generated between the resist film 20a and the side wall of the via-hole 18 is not clear, but the etching gas of NH₃ and N₂/H₂ will make some action to the interface between the resist film 20a and the side wall of the via-hole 18 to thereby lower the adhesion therebetween.

In such background, the inventors of the present application have made earnest studies of the etching conditions for the resist film 20a to be the first to find that N₂/O₂ or N₂/O₂/CF is used as the etching gas, and the chamber internal pressure and the etching gas flow rate are suitably controlled, whereby the generation of cracks between the resist film 20a and the side wall of the via-hole 18 can be prevented, and the resist film 20a can be etched in a good vertical processed configuration.

The etching conditions the inventors of the present application have found will be detailed below.

In the multilayer resist process, generally a lower resist film is processed by using oxygen gas only. In etching a lower resist film by using oxygen gas, the horizontal etching also tends to go on, and the resist film is processed in a bowing configuration. Such bowing configuration does not matter when a pattern size of a semiconductor device is relatively large. However, in processing a fine pattern, such bowing configuration is a problem, such bowing configuration is an obstacle to accurate processing of the fine pattern.

Then, the inventors of the present application studied whether the etching with oxygen gas can be applied to the etching of the resist film 20a in the above-described method for fabricating the semiconductor device and additionally means for preventing the bowing configuration. Resultantly, N₂/O₂ or N₂/O₂/CF gas was used as the etching gas, and the chamber internal pressure and the etching gas flow rate were suitably controlled, whereby the resist film 20a could be etched into a good vertical processed configuration, and the generation of cracks between the resist film 20a and the side wall of the via-hole 18 could be prevented.

FIG. 7 is a graph of the oxygen flow rate ratio dependency of the bowing amount of the etching with N₂/O₂ gas. The bowing amounts are taken on the vertical axis, and the bowing amounts were determined by B-A in which A indicates an opening width of the mask, and B indicates a maximum width of an opening formed in the resist film 20a by using the mask. Flow rate ratios (%) of oxygen gas to a total gas flow rate are taken on the horizontal axis. The flow rate ratios of the oxygen gas were adjusted by diluting the oxygen gas with nitrogen gas. The other etching conditions were a 35 mTorr chamber internal pressure, a 100 W power and a 300 sccm total flow rate of N₂ and O₂, which were fixed.

As shown, the bowing amount is decreased by lowering the flow rate ratio of the oxygen gas. When the flow rate ratio of the oxygen gas is below 10%, the bowing amount is drastically decreased to about 5 nm at 5% and to about 2 nm at 1-3%. A gas to be mixed with the oxygen gas is preferably nitrogen. Mixing, e.g., argon in place of nitrogen cannot suppress the bowing. Although the mechanism for this is not clear, the nitrogen will be acting to protect the side wall of the processed part.

FIG. 8A is a picture of the sectional configuration formed by etching the resist film 20a with oxygen gas only, which was taken by a scanning electron microscope. The etching conditions were a 80 mTorr chamber internal pressure, a 100 W power and a 250 sccm O₂ flow rate. As shown, the resist film 20a is bowed unsuitably for the downsizing.

FIG. 8B is a picture of the sectional configuration formed by etching the resist film 20a with a mixed gas of oxygen and nitrogen, which was taken by a scanning electron microscope. The etching conditions were a 35 mTorr chamber internal pressure, a 100 W power and a 290/10 sccm N₂/O₂ flow rate(oxygen flow rate ratio: 3.3%). As shown, the resist film 20a was processed vertically without bowing configuration. No crack is generated between the resist film 20a and the via-hole 18.

The processed configuration of the resist film 20a is changed depending on the chamber internal pressure.

FIG. 9A is a picture of the sectional configuration formed by etching the resist film 20a with a mixed gas of oxygen and nitrogen under low pressure, which was taken by a scanning electron microscope. The etching conditions other than a 15 mTorr chamber internal pressure were the same as the case of FIG. 8B. As shown, even with the etching gas with nitrogen added to, under a low chamber internal pressure of 15 mTorr, the so-called sub-trench configuration, which has a groove formed on the bottom peripheral part of a trench and a hole deeper than the bottom center thereof, is formed, which affects the later etching.

FIG. 9B is a picture of the sectional configuration formed by etching the resist film 20a under high pressure and with a mixed gas of oxygen and nitrogen, which was taken by a scanning electron microscope. The etching conditions other than a 150 mTorr chamber internal pressure were the same as the case of FIG. 8B. As shown, with the chamber internal pressure as high as 150 mTorr, the resist film 20a is bowed unsuitably for the downsizing.

When N₂/O₂ is used as the etchant for the resist film 20a, the flow rate ratio of the oxygen gas is less than 10%, preferably not more than 5%, more preferably 1-3%. The upper limit value of the flow rate ratio of the oxygen gas can be suitably set in accordance with an allowable bowing amount. The etching rate is lowered by lowing the flow rate ratio of the oxygen gas, and the lower limit value of the flow rate ratio of the oxygen gas can be suitably set in accordance with a prescribed etching rate.

It is preferable to set the chamber internal pressure at 25-50 mTorr, more preferably, at 30-40 mTorr. This is because under a pressure less than 25 mTorr, the etching rate of the resist film 20a is extremely low, and often the sub-trench configuration shown in FIG. 9A is formed. On the other hand, under a pressure of above 50 mTorr, the effect of adding oxygen is enhanced, and the bowing configuration shown in FIG. 9B tends to be formed.

FIGS. 10A-10C are pictures of sectional configurations formed by etching the resist film 20a with N₂/O₂ gas, which were taken by a scanning electron microscope. FIG. 10A is the sectional configuration immediately after the resist film 20a has been etched. FIG. 10B is the sectional configuration immediately after the SiN film 14f and the SiO film 14e have been etched. FIG. 10C is the sectional configuration after the interconnection trench 22 has been formed, and ashing has been performed.

As seen in FIG. 10A, immediately after the resist film 20a has been etched, no crack is generated between the resist film 20a and the side wall of the via-hole 18. The processed configuration of the resist film 20a is vertical. No crack is generated after the SiN film 14f and the SiO film 14e have been etched (FIG. 10B) and after the interconnection trench has been formed (FIG. 10C).

As the etching gas for the resist film 20a, N₂/O₂/CF gas other than N₂/O₂ gas can be used. CF gas (fluorocarbon gas), which forms a protection film on the side wall of an etched part, is expected to prevent the bowing. The use of CF gas can enlarge the process window for etching the resist film 20a. As the CF gas can be used CₓF_{y} or CHₐF_{b} used in the usual semiconductor process, more specifically, C₃F₆, C₄F₈, C₄F₆, C₅F₈, CH₂F₂, CHF₃, CH₃F or others.

FIG. 11 is a graph of the oxygen flow rate ratio dependency of the bowing amount of the etching with N₂/O₂/C₄F₆ gas. The bowing amounts are taken on the vertical axis, and the bowing amounts were determined by B-A in which A indicates an opening width of the mask, and B indicates a maximum width of an opening formed in the resist film 20a by using the mask. Flow rate ratios of oxygen gas (%) to a total gas flow rate are taken on the horizontal axis. The flow rate ratio of the oxygen gas is adjusted by the flow rate of the nitrogen gas. The specific etching conditions are a 35 mTorr chamber internal pressure, a 100 W power, a 60 sccm flow rate of C₄F₆ as the CF gas, a 300 sccm total flow rate of the N₂, O₂ and C₄F₆, which were fixed.

As shown, the bowing amount is decreased by lowering the flow rate ratio of the oxygen gas. When the flow rate ratio of the oxygen is below 12%, the bowing amount is drastically decreased to about 6 nm at 7% and to about 1 nm at 3-5%.

FIG. 12 is a picture of the sectional configuration of the resist film 20a etched with N₂/O₂/C₄F₆, which was taken by a scanning electron microscope. The etching conditions were a 35 mTorr chamber internal pressure, a 100 W power and a 250/5/50 sccm of N₂/O₂/C₄F₆flow rate (oxygen flow rate ratio: about 1.6%). As shown, the processed configuration of the resist film 20a is vertical, and no bowing configuration is generated. No crack is generated even between the resist film 20a and the via-hole 18.

When N₂/O₂/CF is used as the etching gas for the resist film 20a, the flow rate ratio of the oxygen gas is less than 12%, preferably not more than 7%, more preferably not more than 5%. The upper limit value of the flow rate ratio of the oxygen gas is suitably set in accordance with an allowed bowing amount. The etching rate is lowered by lowering the flow rate ratio of the oxygen gas, and the lower limit value of the flow rate ratio of the oxygen gas can be suitably set in accordance with a required etching rate.

It is preferable to set the flow rate ratio of the CF gas at 15-25%. This is because when the flow rate ratio of the CF gas is less than 15%, the effect of forming the protection film is insufficient, and when the flow rate ratio of the CF gas is more than 25%, an organic resist film used as the mask (SOG film 20b) is etched.

Thus, when the resist film 20a is etched with N₂/O₂ as the etching gas, the flow rate ratio of the oxygen gas is set at less than 10%, preferably not more than 5%, more preferably 1-3%. The chamber internal pressure is set at 25-50 mTorr, more preferably 30-40 mTorr. When N₂/O₂/CF is used as the etching gas, the flow rate ratio of the oxygen gas is set at less than 12%, preferably not more than 7%, more preferably not more than 5%. The flow rate ratio of the CF gas is set at 15-25%. Thus, the generation of cracks between the resist film 20a and the side wall of the via-hole 18 can be prevented, and the resist film 20a can be etched in good vertical processed configuration.

As described above, according to the present embodiment, in the dual damascene process of the preceding via mode using a multilayer resist, N₂/O₂ gas or N₂/O₂/CF gas is used in etching a lower resist film for forming an interconnection trench, whereby the generation of cracks between the lower resist film buried in a via-hole and the inter-layer insulating film can be prevented. The processed configuration of the lower resist film can be made vertical.

### Modified Embodiments

The present invention is not limited to the above-described embodiment and can cover other various modifications.

For example, in the above-described embodiment, the present invention is applied to the steps of forming the interconnection trench in the dual damascene process of the preceding via mode using a multilayer resist, but may be applied to other steps. For example, the present invention may be applied to the step of forming the via-hole 18 shown in FIG. 2A. The etching method of the present invention is used to thereby vertically process the resist film 16a suitably for forming fine patterns.

In the above-described embodiment, the interconnection is buried in the inter-layer insulating film of SiN/SiO/SiOC/SiC/SiOC/SiC structure by the dual damascene, but the materials forming the inter-layer insulating film and the layer structure thereof are not limited to the above.

What is claimed is:

1. A method for fabricating a semiconductor device comprising the steps of:
forming an insulating film having a first opening in a first region;
forming an organic resist film over the insulating film and in the first opening;
forming a mask film having etching characteristics different from those of the organic resist film over the organic resist film;
forming a second opening in the mask film in a second region including at least a part of the first region; and
etching the organic resist film with the mask film as a mask,
in the step of etching the organic resist film, the organic resist film being etched with a mixed gas of nitrogen gas and oxygen gas.

2. A method for fabricating the semiconductor device according to claim 1, wherein
a flow rate ratio of the oxygen gas to a total flow rate of the mixed gas is less than 10%.

3. A method for fabricating the semiconductor device according to claim 1, wherein
a flow rate ratio of the oxygen gas to a total flow rate of the mixed gas is 1-3%.

4. A method for fabricating the semiconductor device according to claim 1, wherein
a pressure inside a chamber for etching the organic resist film is 25-50 mTorr.

5. A method for fabricating the semiconductor device according to claim 1, wherein
in the step of etching the organic resist film, the organic resist film is etched, left at least on the bottom of the first opening.

6. A method for fabricating the semiconductor device according to claim 1, wherein
in the step of forming the organic resist film, the organic resist film is formed, having the surface made flat.

7. A method for fabricating the semiconductor device according to claim 1, further comprising, after the step of etching the organic resist film, the step of:
etching the insulating film with the organic resist film as a mask.

8. A method for fabricating the semiconductor device according to claim 1, wherein
the insulating film includes one or more films selected from the group consisting of SiO film, SiN film, SiC film and SiOC film.

9. A method for fabricating the semiconductor device according to claim 1, wherein
the first region is a region for via-hole to be formed in, and
the second region is a region for an interconnection trench to be formed in.
